(19) United States
(12) Patent Application Publication
(10) Pub. No.: US 2026/0194832 A1
(43) Pub. Date: Jul. 9, 2026

(54) SUPPORT STRUCTURE FOR AN ILLUMINATION OPTICAL UNIT OF A PROJECTION EXPOSURE APPARATUS

(71) Applicant: Carl Zeiss SMT GmbH, Oberkochen (DE)

(72) Inventors: Björn LIEBAUG, Ulm (DE); Markus HAUF, Ulm (DE)

(21) Appl. No.: 19/558,596

(22) Filed: Mar. 6, 2026

Related U.S. Application Data
(63) Continuation of application No. PCT/EP2024/071699, filed on Jul. 31, 2024.

(30) Foreign Application Priority Data
Sep. 15, 2023 (DE) 10 2023 208 965.3

(51) Int. Cl. G03F 7/00; G02B 7/182

(52) U.S. Cl. CPC G03F 7/70825; G02B 7/182; G03F 7/7015

(57) ABSTRACT

A support structure open on one side for an illumination optical unit of a microlithographic projection exposure apparatus has a frame extending in a longitudinal direction, with one or more mechanisms for increasing the stiffness of the frame, wherein ribs and/or planar stiffening elements serve as stiffening mechanisms.

### CROSS-REFERENCE TO RELATED APPLICATION

The present application is a continuation of, and claims benefit under 35 USC 120 to, international application No. PCT/EP2024/071699, filed July 31, 2024, which claims benefit under 35 USC 119 of German Application No. 10 2023 208 965.3, filed September 15, 2023. The entire disclosure of each of these applications is incorporated by reference herein.

### FIELD

The disclosure relates to a support structure for an illumination optical unit of a projection exposure apparatus. The disclosure additionally relates to an illumination optical unit, an illumination system, an optical system and a projection exposure apparatus comprising a corresponding support structure. In addition, the disclosure relates to a method for producing a microstructured or nanostructured component and also to a component produced according to the method.

### BACKGROUND

In illumination systems with a small chief ray angle at object (CRAO), the last optical element in the light path upstream of the reticle is arranged near the separating plane between the illumination system and the projection optical unit. A support structure is usually provided for arranging the optical components. On account of the small distance relative to the separating plane, the installation space available for the support structure is typically limited at least in one direction.

### SUMMARY

The disclosure seeks to provide an improved support structure for an illumination optical unit of a projection exposure apparatus.

In accordance with one aspect of the disclosure, the support structure has one or more mechanisms for increasing the stiffness of a frame. For example, a selection from ribs, struts and planar stiffening elements can serve as stiffening mechanisms. For example, partition walls, for example bulkheads, can also serve as stiffening elements. It has been found that, for example, a frame open on one side can be stiffened in a targeted manner by use of surface stiffnesses and/or arrangement of ribs and/or struts. This can make it possible to ensure that the support structure satisfies the ever increasing demands, such as with regard to their mechanical and dynamic properties. The support structure, for example the frame, can be configured for example in such a way that at least the first natural frequency is greater than 100 Hz, for example greater than 200 Hz, for example at least greater than 400 Hz.

It is assumed hereinafter that the projection optical unit and the illumination optical unit of a projection exposure apparatus are substantially arranged in disjoint half-spaces separated from one another by a separating plane. In this case, the separating plane can be oriented for example perpendicular to the object plane in which the reticle is arranged. The separating plane can be oriented for example parallel to the cross-scan direction.

Longitudinal direction is understood hereinafter to be a direction parallel to the chief ray incident on the reticle or a direction perpendicular to the object field. The longitudinal direction deviates from a normal to the object plane generally by at most 30°, for example 20°, for example at most 10°.

The support structure serves for example for arranging optical components. It serves for example for spatially fixing optical components for example within the illumination optical unit. The support structure can be adjustable for example relative to a reference system of the projection exposure apparatus.

Within the illumination optical unit, the support structure itself can form a reference system.

In accordance with one aspect, the frame is open at least sectionally. For example, the frame can be open at least sectionally on one side. It can be open for example on a side facing the separating plane, for example in a transverse direction, i.e. transversely, for example perpendicularly, with respect to the longitudinal direction.

The frame can have an overall extent in the longitudinal direction which is at least equal to the magnitude, for example at least one and a half times the magnitude, for example at least double the magnitude, of its maximum extent in the transverse direction. This has proved to be useful for the arrangement of various components of the illumination optical unit on the frame.

The ribs and/or the stiffening elements can be configured in a profiled fashion. They can have a T-profile, an H-profile, a C-profile, a V-profile or an X-profile in cross-section, for example. As a result, the stiffness can be increased further in specific directions.

In accordance with one aspect, the frame is open over at least 50%, for example at least 60%, for example at least 70%, for example at least 80%, for example at least 90%, of its extent in the longitudinal direction, for example completely, towards a side in a transverse direction with respect to the longitudinal direction. It can be open for example in a direction perpendicular to the longitudinal direction.

The open side can face for example the separating plane between the illumination optical unit and the projection optical unit.

In a further aspect, the support structure has an outwardly plane boundary wall on the side towards which the frame is open. This can make it possible to arrange the support structure as near as possible to the separating plane between the illumination optical unit and the projection optical unit. The separating plane can lie for example in the region of the free area of the boundary wall.

In accordance with a further aspect, the frame can have a triangular cross-section or a trapezium-shaped cross-section or a pentagonal cross-section at least sectionally in a transverse, for example perpendicular, direction with respect to the longitudinal direction. Generally, the cross-section of the frame in a transverse, for example perpendicular, direction with respect to the longitudinal direction can be configured in a polygonal fashion at least sectionally.

The support structure can be configured for example in such a way that the frame has a triangular cross-section at a first position in the longitudinal direction and a trapezium-shaped cross-section at a second position in the longitudinal direction.

Particularly high stiffnesses can be achieved by way of a triangular and/or a trapezium-shaped and/or a pentagonal cross-section.

In this case, a trapezium is understood to be for example a non-rectangular and non-parallelogram-shaped trapezium. The trapezium has for example parallel base sides having different lengths. As a result, shear tolerances can be reduced, for example avoided.

In accordance with a further aspect, the frame can be bounded by three or more triangular or trapezium-shaped stiffening plates in the longitudinal direction. The frame can be bounded by three triangular stiffening plates in the longitudinal direction, for example.

The frame can have a smallest convex envelope which is bounded exclusively by triangular and quadrilateral, for example trapezium-shaped, surfaces.

The frame can have for example a pyramidal smallest convex envelope. In this case, the base surface of the envelope can be configured in a trapezium-shaped, non-rectangular or rectangular fashion. The base surface faces the separating plane, for example. It can be oriented parallel to the separating plane, for example.

The vertex of the pyramid can be situated perpendicularly above a boundary edge of the base surface.

The planar stiffening elements, for example the stiffening plates, can be mounted for example tangentially on a frame.

The frame can be configured with at least sectionally a C-shaped cross-section.

In accordance with a further aspect, the frame can have receptacles for receiving optical components at opposite ends in the longitudinal direction. The optical components can be for example facet mirrors of the illumination optical unit.

Generally, the frame can have connection points for attachments. The attachments can be for example optical, mechanical or electrical components, for example modules, of the projection exposure apparatus, for example of the illumination optical unit. The attachments can have their own attachment housing, for example.

Receiving optical components and/or attachments, for example modules, in corresponding receptacles of the frame enables the stiffness of the frame to be further improved. It is possible, for example, to use the stiffness of the optical components and/or of the attachments, for example the housings thereof, for stiffening the support structure.

The corresponding optical components and/or attachments can be fixedly or releasably connected to the frame. They can be screwed, clamped or welded to the frame, for example. All kinds of interlocking or force-locking connection techniques can be used. However, integral bonding is not ruled out here.

In accordance with a further aspect, one or more stiffening elements can be arranged in the interior of the frame. These can be oriented parallel to the longitudinal direction, perpendicular to the longitudinal direction or obliquely with respect to the longitudinal direction.

For example, struts or plates can serve as stiffening elements. The plates can have cutouts. The cutouts can be configured for example in a manner shaped as conic sections, for example in parabolic or elliptic fashion, for example in circular fashion.

Stiffening elements oriented transversely with respect to the longitudinal direction are also referred to as transverse stiffenings or transverse stiffening elements.

Stiffening elements oriented substantially parallel to the longitudinal direction can serve as separating plates between rectilinear sections in a folded beam path, for example a narrowly folded beam path, of the illumination optical unit.

One, two, three or more intermediate bases can be arranged within the support structure, for example in the frame. These can serve as transverse stiffenings.

The support structure can be configured for example in such a way that it defines an interior configured in such a way that it enables an obstruction-free radiation path with individual rectilinear subsections having a length of in each case at least 1 meter (m), for example at least 1.5 m, for example at least 2 m.

The subsections can be configured for example in such a way that they form radiation-conical regions or radiation-frustoconical regions between on one side an intermediate focus and on the other side a first optical element, for example a (the) first facet mirror, and/or between the first optical element, for example a (the) first facet mirror, and a second optical element, for example a (the) second facet mirror, and/or between the second optical element, for example a (the) second facet mirror, a third optical element and/or a fourth optical element and/or the object field.

The chief ray angle and/or the folding angles in the beam path of the illumination optical unit can be for example at most 10°, for example at most 7°, for example at most 6°.

It has been found that a support structure according to the disclosure results in a reduction of costs and a mass saving. Moreover, the manufacturing accuracy was able to be reduced. The use of welding assemblies has resulted in greater freedom of design. The proposed type of construction with ribs and/or intermediate bases can facilitate the separation of the support structure along the intermediate bases. These additionally can provide the surfaces used for a connection of the modules (screw flanges or weld joints). Such modularization can be cost-effective since the raw blocks are smaller and can be produced more economically and generally the degree of machining (and thus manufacturing outlay and time) is lower than in the case of a large monolithic structure.

The mass saving can be already afforded, inter alia, owing to the triangular or trapezium-shaped or polygonal basic shape, which allows less voluminous (and hence lighter) support structures than the customary type of construction in a rectangular shape.

Further features of the disclosure include improving an illumination optical unit, an illumination system, an optical system for a projection exposure apparatus, and also a projection exposure apparatus.

Such optical units/systems can comprise a support structure in accordance with the description above.

In accordance with one aspect, at least one optical component can be supported by the support structure. It is possible, for example, to position one or two facet mirrors in the beam path of the illumination optical unit with the aid of the support structure. The optical components, for example the mirrors, can be positioned particularly precisely on account of the mechanical properties of the support structure. Where an arrangement of mirrors, for example facet mirrors, on the support structure is described hereinafter, this should be understood as non-limiting. The corresponding statements can also relate to other optical components.

It is possible, for example, for optical components, for example one or two facet mirrors, to be arranged on the frame of the support structure, for example to be connected to the frame. The two facet mirrors can be arranged thereon opposite one another, for example. The two facet mirrors can be connected to the frame in each case at the end side on the frame, for example.

The support structure can be arranged in the illumination optical unit for example in such a way that it is open in direction to the separating plane towards the projection optical unit.

The support structure can lie for example completely in a half-space which faces away from the projection optical unit and which is defined by a plane perpendicular to the object plane, for example parallel to the cross-scan direction.

In accordance with one aspect, a chief ray angle at object can be at most 10°, for example at most 7°, for example at most 6°.

In accordance with a further aspect, a distance between the last optical element in the beam path of the illumination radiation upstream of the reticle, for example the last mirror, for example the second facet mirror, and a plane bounding the support structure towards the open side can be at most 10 centimeters (cm), for example at most 5 cm, for example at most 3 cm, for example at most 2 cm, for example at most 1 cm.

In accordance with a further aspect, an object-side numerical aperture can be at least 0.3, for example at least 0.5.

An illumination system has, besides an illumination optical unit in accordance with the description above, a radiation source for generating illumination radiation, for example an EUV radiation source. For example, illumination radiation in the EUV range, for example having a wavelength of less than 30 nanometers (nm), for example less than 15 nm, can be generated via an EUV radiation source.

An optical system can comprise an illumination optical unit in accordance with the description above and a projection optical unit for transferring illumination radiation from the object field into an image field.

A projection exposure apparatus has, besides an illumination system in accordance with the description above, a projection optical unit for transferring illumination radiation from the object field into an image field.

A method for producing a microstructured or nanostructured component can be improved by providing a projection exposure apparatus in accordance with the description above. The improved mechanical properties of the support structure can enable the microstructured or nanostructured components to be produced more precisely.

In accordance with the method, a reticle, with structures to be imaged, is arranged in the object field of the illumination optical unit. The structures of the reticle are imaged with the aid of illumination radiation, for example in the EUV range, onto a radiation-sensitive layer of a wafer arranged in the image field of the projection optical unit. Further details of the method are known from the prior art, for example WO 2019/174 996 A1, to which reference is hereby made.

### BRIEF DESCRIPTION OF THE DRAWINGS

Further features and details of the disclosure will become apparent from the description of exemplary embodiments with reference to the figures, in which:

FIG. 1 schematically shows certain constituent parts and the beam path in a projection exposure apparatus;

FIG. 2 schematically shows an arrangement of an optical component near to a separating plane between the illumination optical unit and the projection optical unit;

FIG. 3 schematically shows an exemplary illustration of a support structure for an illumination optical unit;

FIG. 4 schematically shows a view of the support structure in accordance with FIG. 3 from above;

FIG. 5 schematically shows an illustration of a support structure of an illumination optical unit with a highlighted frame; and

FIG. 6 schematically shows a view of the frame in accordance with FIG. 5 for elucidating further details.

### DETAILED DESCRIPTION

A microlithographic projection exposure apparatus 1 serves for producing a microstructured or nanostructured electronic semiconductor component. A light or radiation source 2 emits EUV radiation 3 in the wavelength range of, for example, between 0.2 nm and 30 nm, for example between 0.1 nm and 15 nm.

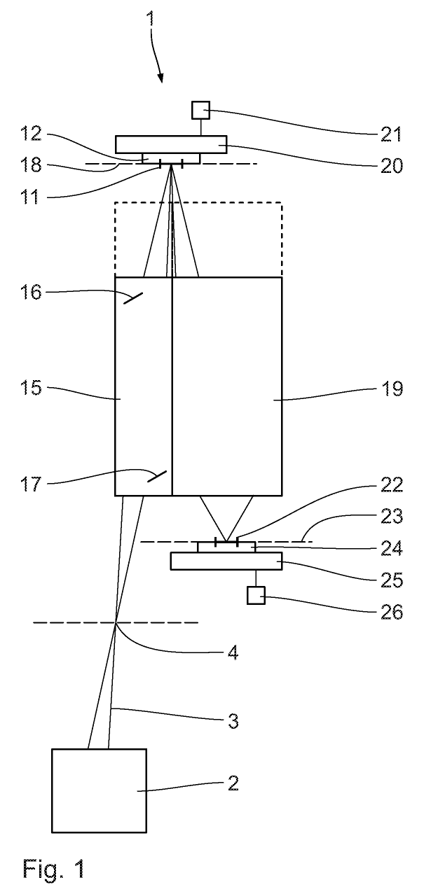

FIG. 1 shows main components of one of the projection exposure apparatuses 1 highly schematically.

The radiation source 2 is part of a radiation source module. Proceeding from the radiation source module, the illumination and imaging light 3 passes through an intermediate focus 4 and from there is guided by an illumination optical unit 15 towards an object field 11 of the projection exposure apparatus 1, in which object field a lithography mask 12 in the form of a reticle as object to be projected is arranged.

The illumination optical unit 15 includes a field facet mirror 16 and a second facet mirror, which is referred to hereinafter as pupil facet mirror 17 even if this mirror need not be arranged in a pupil plane, the function of which mirrors corresponds to that known from the prior art, and which are therefore merely illustrated extremely schematically and without the associated EUV beam path in FIG. 1.

After reflection at the field facet mirror 16, the EUV pencil of rays is incident on the pupil facet mirror 17. The individually actuatable subelements of the first optical element are assigned to those of the second optical element depending on a desired illumination by the projection exposure apparatus 1. The illumination light 3 is therefore guided for predefining individual illumination angles along the illumination channel sequentially via pairs comprising in each case one or more individual subelements of the first and second optical elements. These subelements are each tilted individually for control purposes.

Via the pupil facet mirror 17 and, if appropriate, via a downstream transfer optical unit (not illustrated), the individual light portions are imaged into the illumination or object field 11 in a reticle or object plane 18 of a projection optical unit 19 (likewise illustrated schematically in FIG. 1) of the projection exposure apparatus 1.

In a further embodiment of the illumination optical unit 15, for example given a suitable position of an entrance pupil of the projection optical unit 19, it is also possible to dispense with the mirrors of the transfer optical unit upstream of the object field 11, which leads to a corresponding increase in the transmission of the projection exposure apparatus 1 for the used radiation beam.

The reticle 12, which reflects the used radiation beam, is arranged in the object plane 18 in the region of the object field 11. The reticle 12 is carried by a reticle holder 20, which is displaceable in a manner controlled by a reticle displacement drive 21.

The projection optical unit 19 images the object field 11 into an image field 22 in an image plane 23. During the projection exposure, a wafer 24 is arranged in the image plane 23, the wafer bearing a light-sensitive layer which is exposed during the projection exposure by the projection exposure apparatus 1. The wafer 24 is carried by a wafer holder 25, which is in turn displaceable in a manner controlled by a wafer displacement drive 26.

During the projection exposure, both the reticle 12 and the wafer are scanned in a synchronized manner in the scan direction by corresponding control of the reticle displacement drive 21 and of the wafer displacement drive 26. The wafer can be scanned at a scan rate of typically 600 mm/s in the x-direction during the projection exposure.

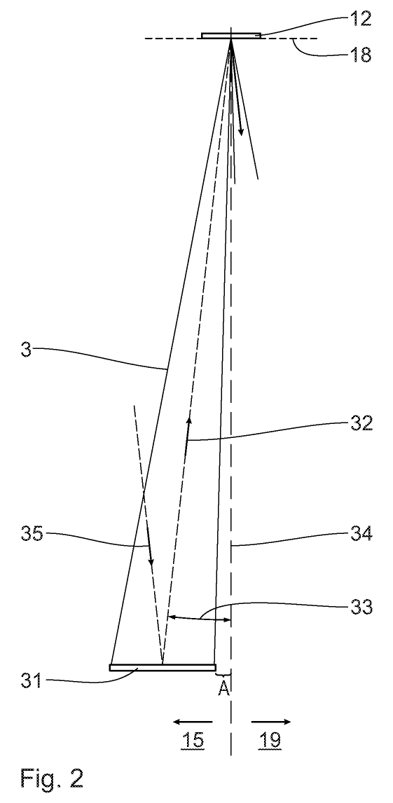

FIG. 2 illustrates schematically and by way of example the installation space conditions between the last optical element 31 in the beam path of the illumination optical unit 15 and the reticle 12.

The illumination radiation 3 has a chief ray direction 32. The chief ray direction can be characterized by the chief ray angle 33. The emission angle 33 is also referred to as the chief ray angle at object for incidence on the reticle 12.

FIG. 2 schematically illustrates a separating plane 34 between the illumination optical unit 15 and the projection optical unit 19. The separating plane 34 can be oriented for example perpendicular to the object plane 18.

The separating plane 34 defines the virtual separation between the half-space in which the illumination optical unit 15 is arranged and the half-space in which the projection optical unit 19 is arranged.

Given a small beam angle 33, the distance A between the last optical element 31 of the illumination optical unit 15 and the separating plane 34 is very small. For example, besides being dependent on the chief ray angle 33, the distance A is also dependent on the size, for example the extent, of the last optical element 31 in a direction perpendicular to the separating plane 34.

The distance A is used for optical production methods and/or a module mechanism (not illustrated) enclosing the optical element 31.

Merely for elucidation purposes, FIG. 2 also illustrates a beam 35 incident on the last optical element 31. Particularly if the beam path in the illumination optical unit 15 is narrowly folded, the reduced installation space availability associated therewith results in difficulty with respect to a support structure 36 used for supporting, i.e. positioning, the optical components of the illumination optical unit.

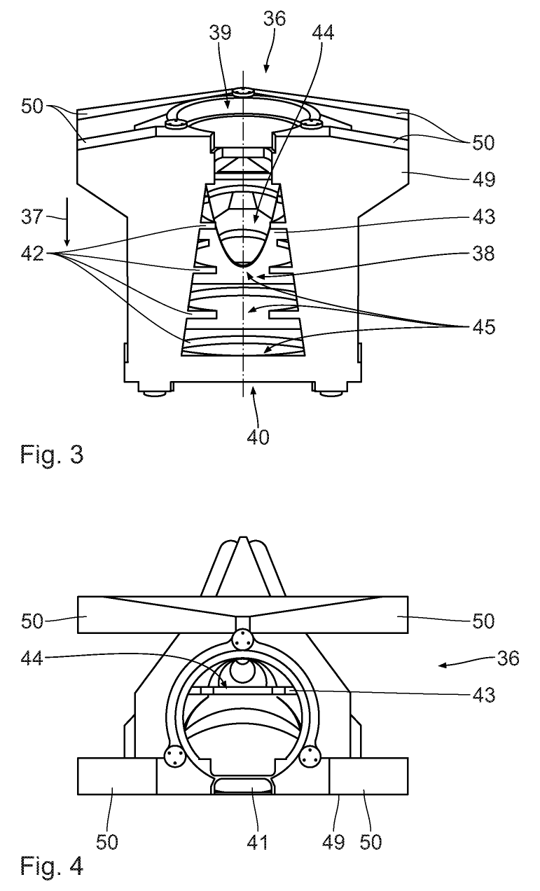

Such a support structure 36 is illustrated by way of example in FIGS. 3 and 4.

The support structure 36 is open on one side. It has for example an opening 38 extending in a longitudinal direction 37.

In this case, the longitudinal direction 37 can coincide with a normal object plane 18 or can be parallel to such a normal direction.

The support structure 36 has a first receptacle 39 for receiving a first optical element. The first receptacle is the upper receptacle in FIG. 3. This should be understood as non-limiting. The support structure 36 can also be arranged in a differently oriented manner in the projection exposure apparatus 1.

The first optical element that can be arranged in the first receptacle 39 can be for example a first facet mirror, for example the field facet mirror 16. The first optical element is received in the first receptacle 39 in a manner connected to the support structure 36 for example fixedly or by way of a compensating element. The compensating element can serve for example for compensation of thermal expansion or dynamic decoupling or setting (adjustment) of the optical elements. The optical element or the compensating element can be screwed, clamped or welded to the support structure 36, for example.

At the opposite end in the longitudinal direction 37, the support structure has a second receptacle. The second receptacle 40 serves for receiving a second optical element. The second optical element can be a second mirror, for example a second facet mirror, for example the pupil facet mirror 17.

An open region 41 is discernible in FIG. 4. Through the open region 41 the illumination radiation 3 passes from the last optical element 31 of the illumination optical unit 15 to the object field 11.

A plurality of transverse stiffenings 42 are arranged in the support structure 36. For example, stiffening plates can serve as transverse stiffenings 42. The stiffening plates can each have cutouts 45 enabling the obstructed passage of illumination radiation 3.

The cutouts 45 can each be configured in elliptic fashion, for example in circular fashion.

A longitudinal stiffening 43 is arranged in the support structure 36. A stiffening plate serves as longitudinal stiffening 43. A cutout for allowing EUV radiation 3 to pass through can be provided for the longitudinal stiffening. As is illustrated schematically and by way of example in FIG. 3, the cutout 44 in the longitudinal stiffening 43 can be configured in parabolic fashion.

The support structure 36 encloses the beam path of the illumination optical unit 15 substantially in the shape of the letter C. The support structure 36 thus constitutes a structure open on one side.

The support structure 36 has a plane boundary wall 49 towards the open side. The free surface of the boundary wall 49 can coincide with the separating plane 34. It can be generally oriented parallel to the separating plane 34.

Using lateral projections 50, the support structure 36 can be arranged, for example secured, on bearing supports in the projection exposure apparatus 1.

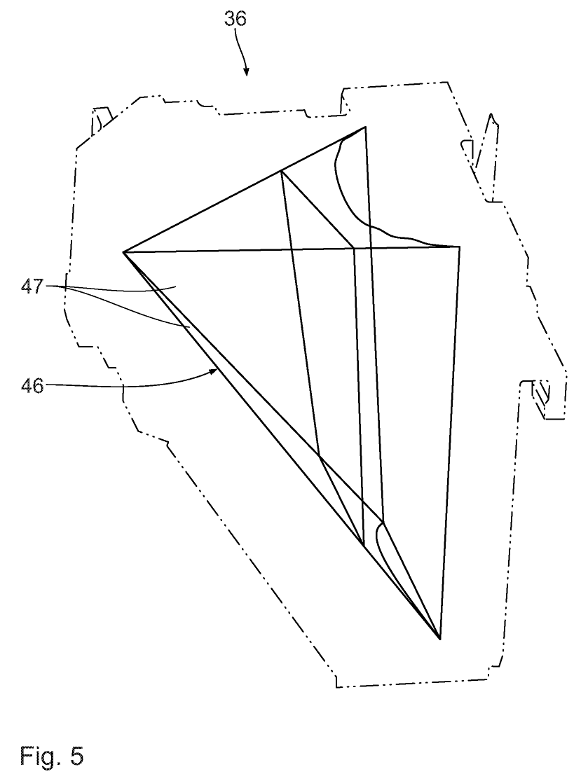

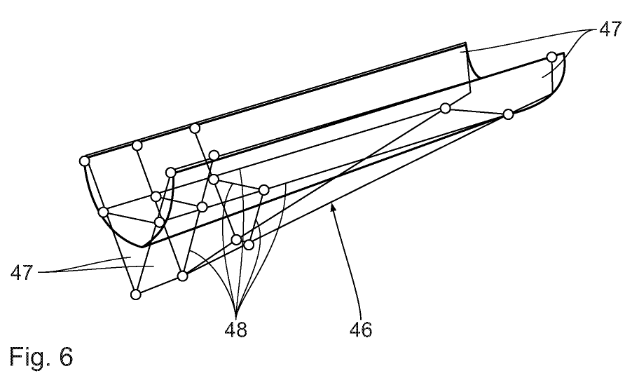

In order to increase the stiffness, for example the torsional stiffness, of the support structure 36, the latter can have a frame 46. The frame 46 is highlighted by way of example in FIG. 5. It is illustrated purely schematically in FIGS. 5 and 6.

The frame 46 can be further stiffened with the aid of the ribs 48. In this case, the ribs 48 can form shaping ribs of the frame 46. An outer skin, for example in the form of the stiffening plates 47, can then be applied to the ribs.

The frame 40 with ribs 48 and/or stiffening plates 47 allows, for example on account of the regular structure, the manufacture of small subsections which can be connected to form the complete support structure 36. The costs and the desired manufacturing accuracies can be reduced as a result.

On account of the triangular and/or trapezium-shaped cross-section, for example in combination with the rib type of construction, it is possible to achieve a saving of mass and volume and hence a reduction of the degree of machining in comparison with support structures having rectangular cross-sections.

The support structure 36 can be configured as a welding assembly. This affords greater freedom of design on account of a desirable segmentation.

In addition, smaller raw material sections are more easily procurable and more easily producible and manageable with regard to their material quality and material homogeneity.

What is claimed is:

1. A support structure, comprising:
a frame extending in a longitudinal direction, the frame only partly circumferentially surrounding a radiation cross-sectional region in a plane perpendicular to the longitudinal direction; and
a mechanism configured to increase a stiffness of the frame, the mechanism comprises a member selected from the group consisting of a rib, a strut, and a planar stiffening element.

2. The support structure of claim 1, wherein, over at least 50% of an extent of the frame in the longitudinal direction, the frame is open toward one side in a transverse direction with respect to the longitudinal direction.

3. The support structure of claim 2, wherein the support structure comprises an outwardly plane boundary wall on a side toward which the frame is open.

4. The support structure of claim 1, wherein the frame has a triangular or trapezium-shaped or pentagonal cross-section at least sectionally in a transverse direction with respect to the longitudinal direction.

5. The support structure of claim 1, further comprising a stiffening plate that bounds the frame in the longitudinal direction, and the stiffening plate is triangular or trapezium-shaped.

6. The support structure of claim 1, comprising three or four substantially triangular planar stiffening elements which bound the frame towards the outside.

7. The support structure of claim 1, wherein the frame comprises receptacles configured to receive optical components at opposite ends in the longitudinal direction.

8. The support structure of claim 1, the stiffening mechanism comprises a stiffening element in an interior of the frame.

9. The support structure of claim 1, comprising a plurality of stiffening mechanisms configured to increase the stiffness of the frame, wherein each of the stiffening mechanisms comprises a member selected from the group consisting of a rib, a strut, and a planar stiffening element.

10. The support structure of claim 9, wherein, over at least 50% of an extent of the frame in the longitudinal direction, the frame is open toward one side in a transverse direction with respect to the longitudinal direction.

11. The support structure of claim 9, wherein the frame has a triangular or trapezium-shaped or pentagonal cross-section at least sectionally in a transverse direction with respect to the longitudinal direction.

12. An illumination optical unit, comprising:
a support structure according to claim 1; and
an optical component supported by the support structure.

13. The illumination optical unit of claim 12, wherein the illumination optical unit has a chief ray angle at object of at most 10°.

14. The illumination optical unit of claim 12, wherein a distance between a last optical element of the illumination optical element in a beam path of the illumination optical element and a plane bounding the support structure towards the open side is at most 15 centimeters.

15. The illumination optical unit of claim 12, wherein the illumination optical unit has an object-side numerical aperture of at least 0.3.

16. The illumination optical unit of claim 15, wherein:
the illumination optical unit has a chief ray angle at object of at most 10°; and
a distance between a last optical element of the illumination optical element in a beam path of the illumination optical element and a plane bounding the support structure towards the open side is at most 15 centimeters.

17. An illumination system, comprising:
a radiation source configured to generate illumination radiation; and
an illumination optical unit, comprising:
a support structure according to claim 1; and
an optical component supported by the support structure.

18. An optical system, comprising:
an illumination optical unit, comprising:
a support structure according to claim 1; and
an optical component supported by the support structure; and
a projection optical unit configured to transfer the illumination radiation from an object field into an image field.

19. A microlithographic projection exposure apparatus, comprising:
an illumination system, comprising:
a radiation source configured to generate illumination radiation; and
an illumination optical unit, comprising:
a support structure according to claim 1; and
an optical component supported by the support structure; and
a projection optical unit configured to transfer the illumination radiation from an object field into an image field.

20. A method of using a microlithographic projection exposure apparatus comprising an illumination optical unit and a projection optical unit, the method comprising:
using the illumination optical unit to illuminate an object in an object plane of the projection optical unit; and
using the projection optical unit to image the illuminated object into an image plane of the projection optical unit,
wherein the illumination optical unit comprises:
a support structure according to claim 1; and
an optical component supported by the support structure.
